(19) United States
(12) Patent Application Publication
(10) Pub. No.: US 2016/0158890 A1
(43) Pub. Date: Jun. 9, 2016

(54) SYSTEMS AND METHODS FOR SCRIBING PHOTOVOLTAIC STRUCTURES

(71) Applicant: SolarCity Corporation, San Mateo, CA (US)

(72) Inventors: Pablo Gonzalez, Fremont, CA (US); Bobby Yang, Los Altos Hills, CA (US); Peter Phuc Nguyen, San Jose, CA (US)

(73) Assignee: SolarCity Corporation

(21) Appl. No.: 14/804,306

(22) Filed: Jul. 20, 2015

Related U.S. Application Data
(60) Provisional application No. 62/088,509, filed on Dec. 5, 2014.
(60) Provisional application No. 62/143,694, filed on Apr. 6, 2015.

(51) Int. Cl. B23K 26/36; H01L 21/66; H01L 31/18; B23K 26/40

(52) U.S. Cl. CPC B23K 26/367; B23K 26/4075; H01L 22/26; H01L 31/18

(57) ABSTRACT

A system for scribing a photovoltaic structure is provided. During operation, a conveyor can move a photovoltaic structure along a path, and a scribing apparatus is directed toward that path to scribe a groove of a predetermined depth. In one embodiment, the groove does not penetrate an interface between a base layer and an emitter layer of the photovoltaic structure.

### CROSS-REFERENCE TO OTHER APPLICATIONS

This claims the benefit of U.S. Provisional Patent Application No. 62/088,509, Attorney Docket Number P103-1PUS, entitled “SYSTEM, METHOD, AND APPARATUS FOR AUTOMATIC MANUFACTURING OF SOLAR PANELS,” filed Dec. 5, 2014; and U.S. Provisional Patent Application No. 62/143,694, Attorney Docket Number P103-2PUS, entitled “SYSTEMS AND METHODS FOR PRECISION AUTOMATION OF MANUFACTURING SOLAR PANELS,” filed Apr. 6, 2015; the disclosures of which are incorporated herein by reference in their entirety for all purposes.

This is also related to U.S. patent application Ser. No. 14/563,867, Attorney Docket Number P67-3NUS, entitled “HIGH EFFICIENCY SOLAR PANEL,” filed Dec. 8, 2014; and U.S. patent application Ser. No. 14/510,008, Attorney Docket Number P67-2NUS, entitled “MODULE FABRICATION OF SOLAR CELLS WITH LOW RESISTIVITY ELECTRODES,” filed Oct. 8, 2014; the disclosures of which are incorporated herein by reference in their entirety for all purposes.

### FIELD OF THE INVENTION

This relates to solar panel fabrication, including scribing a groove along a busbar of a photovoltaic structure prior to dividing the solar cell into multiple cell strips.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A solar cell may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technology, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete solar cells. Adjacent solar cells in a string may overlap one another in a cascading arrangement. For example, continuous strings of solar cells that form a solar panel are described in U.S. patent application Ser. No. 14/510,008, filed Oct. 8, 2014 and entitled “Module Fabrication of Solar Cells with Low Resistivity Electrodes,” the disclosure of which is incorporated by reference in its entirety. Producing solar panels with a cascaded cell arrangement can reduce the resistance due to inter-connections between the strips, and can increase the number of solar cells that can fit into a solar panel.

One method of making such a panel includes sequentially connecting the busbars of adjacent cells and combining them. One type of panel (as described in the above-noted patent application) includes a series of cascaded strips created by dividing complete solar cells into strips, and then cascading the strips to form one or more strings.

Precise and consistent division of solar cells into strips and alignment of strips or cells when forming a cascade arrangement is critical to ensure proper electrical and physical connections, but such alignment cannot be reliably achieved in high volumes if performed manually.

### SUMMARY

One embodiment of the present invention provides a system for scribing a photovoltaic structure. During operation, a conveyor moves a photovoltaic structure along a path. A scribing apparatus directed toward the path scribes a groove of a predetermined depth on the photovoltaic structure while the photovoltaic structure moves along the path. The groove does not penetrate an interface between a base layer and an emitter layer of the photovoltaic structure.

In some embodiments, the predetermined depth is approximately 2%-70% of a thickness of the photovoltaic structure.

In some embodiments, the predetermined depth is approximately 10%-40% of the thickness of the photovoltaic structure.

In some embodiments, the scribing apparatus includes a laser scribing tool, a mechanical scribing tool, an acoustic scribing tool, a scribing tool based on temperature differential, or any combination thereof.

In some embodiments, the scribing apparatus includes a laser scribing tool. Furthermore, a control module can turn on the laser scribing tool upon the photovoltaic structure reaching a first position, and can turn off the laser scribing tool upon the photovoltaic structure leaving a second position.

In some embodiments, the system includes a position detection module to detect the position of the photovoltaic structure. Furthermore, an alignment module aligns the scribing apparatus based on the position of the photovoltaic structure, thereby allowing the groove to be formed at a desired position.

In some embodiments, the groove is formed near and substantially parallel to a busbar on the photovoltaic structure.

In some embodiments, the scribing apparatus includes two scribing tools to scribe two grooves on the photovoltaic structure, thereby facilitating division of the photovoltaic structure into three strips.

In some embodiments, the scribing apparatus includes a scribing tool and an adjustment module that adjusts the distance between the scribing tool and a surface of the photovoltaic structure.

### BRIEF DESCRIPTION OF THE FIGURES

FIG. 1A shows a scribing system according to an embodiment of the invention.

FIG. 1B shows a photovoltaic structure, according to an embodiment of the invention.

FIG. 2A shows a photovoltaic structure according to one embodiment of the invention.

FIG. 2B shows a cross-sectional view of a photovoltaic structure prior to being cleaved, according to one embodiment of the invention.

FIG. 2C shows a cascaded arrangement of three strips after a photovoltaic structure is cleaved, according to one embodiment of the invention.

FIG. 2D shows an exemplary conductive grid and blank space pattern on the front surface of a photovoltaic structure, according to one embodiment of the invention.

FIG. 2E shows an exemplary conductive grid and blank space pattern on the back surface of a photovoltaic structure, according to one embodiment of the invention.

FIG. 2F shows multiple strips, according to one embodiment of the invention.

FIG. 3 shows a sequence of steps for processing photovoltaic structures to produce a string according to one embodiment of the invention.

FIG. 4 shows a scribing system according to an embodiment of the invention.

FIG. 5 shows an exemplary scribe-controlling apparatus according to an embodiment of the invention.

FIG. 6 shows an exemplary method for scribing a groove near inner busbars of a photovoltaic structure according to an embodiment of the invention.

FIG. 7 shows an exemplary photovoltaic structure verification station according to an embodiment of the invention.

FIG. 8 shows an exemplary scribing apparatus according to an embodiment of the invention.

FIG. 9 shows a front view of a scribe mount according to an embodiment of the invention.

FIG. 10 shows a fixed scribe mount according to an embodiment of the invention.

FIG. 11 shows a scribing apparatus mount according to an embodiment of the invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

A scribing system is provided that solves the problem of automatically scribing a photovoltaic structure before dividing the photovoltaic structure into strips. The scribing system can operate within an automated assembly line that can manufacture complete solar panels, which may include photovoltaic structure strips arranged in a cascaded configuration.

The scribing system can receive a photovoltaic structure on a conveyor, and may scribe a groove next to or near a busbar of the photovoltaic structure. The groove may be any orientation with respect to the busbar, but is normally substantially parallel to it. The scribing system can use an image sensor to detect the location of each busbar with respect to the conveyor, and may use an actuator to align the scribing system at a predetermined position with respect to (e.g., at a certain distance from) a corresponding busbar of the photovoltaic structure. In some embodiments, the scribe system can include a laser scribing tool (or other types of scribing mechanism) that can scribe a groove near a busbar, to facilitate subsequent division of the photovoltaic structure into multiple strips.

Later stages of the solar-panel assembly line may divide the photovoltaic structure along the scribed groove, and may arrange a plurality of strips into one or more cascaded strings. The solar-panel assembly line can then combine multiple strings to produce one or more solar panels. In some embodiments, the photovoltaic structures may be divided by applying a temperature differential in addition to, or instead of, a laser scribing process. In this embodiment, a temperature gradient is formed (e.g., one side of the cell can be exposed to a low temperature while the other side can be exposed to a higher temperature). As a result of the temperature differential, the cell can be induced to separate between the two temperature regions.

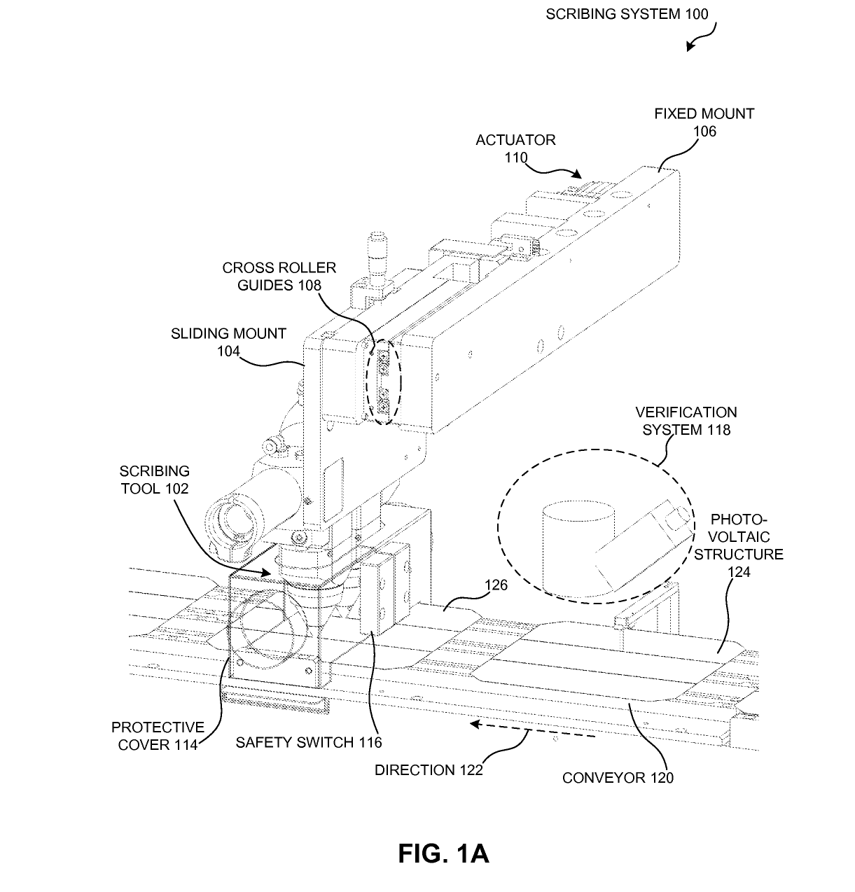

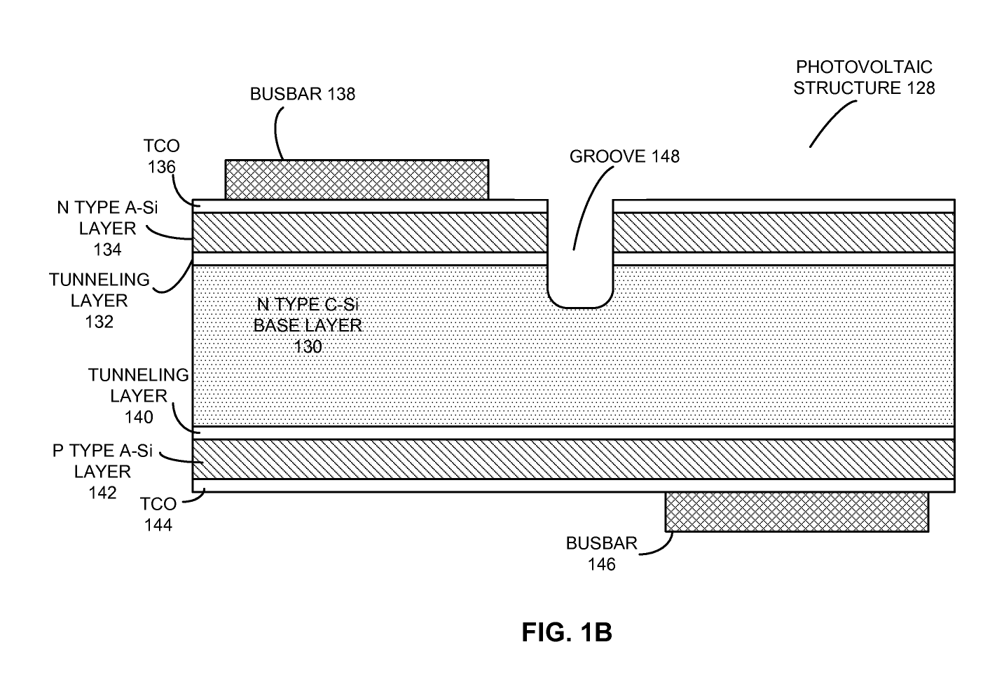

FIG. 1A shows scribing system 100 according to an embodiment of the invention. Scribing system 100 can include at least one scribing tool 102 mounted on sliding mount 104. Scribing tool 102 can emit a laser beam, for example, onto the top surface of photovoltaic structure 126 while conveyor 120 moves photovoltaic structure 126 along direction 122, which can be, for example, in a substantially horizontal plane to reduce the need for additional support. The laser beam can scribe a groove onto the top surface of photovoltaic structure 126, where the intensity of the laser beam and/or the speed of conveyor 120 can be adjusted based on the desired depth of the groove. Other scribing methods, including mechanical, acoustic, and temperature-based methods, can be used.

The preferred or predetermined depth of the scribed grooves can vary, depending on physical constraints such as the thickness, the intrinsic material properties, and the temperature, etc., of the photovoltaic structure. In general, the groove can be scribed on either side of the photovoltaic structure. In one embodiment, to reduce the likelihood of damage to the interface between the base layer and the emitter layer, the groove can be scribed on a side that is opposite to such interface. Such damage could occur from high temperature if a laser scribing tool is used, or from mechanical forces if other scribing methods are used. In this case, the groove can penetrate, on the side where the surface field layer is located, a transparent conductive oxide (TCO) layer, a heavily doped emitter layer, an optional intrinsic tunneling layer, and a portion of a crystalline Si base layer. The groove depth can be sufficiently large to facilitate precise mechanical cleaving without the laser beam (if laser is used for scribing) reaching the base-layer-to-emitter-layer interface to cause any damage to this interface.

FIG. 1B shows one example of how the groove can be formed to prevent damage to the emitter junction of a photovoltaic structure. Photovoltaic structure 128 in this example includes N type lightly doped crystalline silicon (c-Si) base layer 130, intrinsic tunneling layer 132, N type heavily doped amorphous silicon (a-Si) surface field layer 134, transparent conductive oxide (TCO) layer 136, and front-side busbar 138. On the backside, the structure can include intrinsic tunneling layer 140, P type a-Si emitter layer 142, TCO layer 144, and backside busbar 146. The backside tunneling junction, formed by P type a-Si emitter layer 140, intrinsic tunneling layer 140, and N type c-Si base layer 130, can transport away the majority carriers generated by base layer 130. The front side tunneling junction, formed by N type heavily doped a-Si surface field layer 134, intrinsic tunneling layer 132, and base layer 130, can transport away the minority carriers generated by base layer 130, thereby reducing the amount of carrier recombination in base layer 130. Tunneling layers 132 and 140 can passivate the interface between base layer 130 and the two heavily doped a-Si layers while still allowing carriers generated by base layer 130 to enter these a-Si layers due to tunneling effect.

The tunneling junction between base layer 130 and emitter layer 142 is where the majority carriers are removed. It is therefore preferable that the damage caused by scribing and/or cleaving to this interface is kept small. If a laser is used for scribing, the high temperature caused by the laser beam can damage the base-layer-to-emitter junction. Hence, it is desirable to scribe groove 148 on the surface-field-layer side, where groove 148 does not penetrate base layer 130 and reach the base-layer-to-emitter interface. A mechanical cleaving process can be used after the scribing process to attain a clean-cut breakage along the groove. More details of an exemplary photovoltaic structure are provided in U.S. patent application Ser. No. 13/601,441, filed Aug. 31, 2012, entitled “BACK JUNCTION SOLAR CELL WITH TUNNEL OXIDE,” the disclosure of which is hereby incorporated by reference in its entirety herein.

Exemplary photovoltaic structure 128 shown in FIG. 1B includes an N type lightly doped c-Si base layer. In general, the base layer can be either N or P type doped, or undoped, and can be made of a variety of materials, including c-Si, a-Si, poly-crystalline silicon, or non-silicon materials. Various device structures and designs based on different materials can also be used to construct the photovoltaic structure. For example, the photovoltaic structure can be a wafer-based solar cell, or a thin film solar cell, which might have a size and shape different from those of regular wafers. Preferred embodiments of the present invention provide a system that can scribe a groove on a photovoltaic structure that does not penetrate the interface between the base layer and emitter layer.

For example, for a typical crystalline-Si-based photovoltaic structure with a stack thickness ranging from 200 to 700 microns, the groove depth can range from 5 to 100 microns. Preferably, the groove depth can be up to 30 or 50 microns. In one embodiment, the depth of the groove can be approximately 20 microns. For thin-film-based photovoltaic structures with a small stack thickness, the groove depth can be reduced correspondingly. Alternatively, the groove depth can be measured as a percentage of the thickness of the photovoltaic structure. The depth of the groove can be, for example, up to 70% of the thickness of the photovoltaic structure. In one embodiment, the depth of the groove can be 2%-70% of the thickness of the photovoltaic structure. In a further embodiment, the groove depth can be 10%-40% of the structure's thickness. Preferably, the groove depth can be approximately 20% of the structure's thickness.

In one embodiment, the depth of the groove can be controlled by adjusting the laser power of the scribing tool and/or the speed at which the photovoltaic structure moves across the laser beam. This speed can in turn be controlled by adjusting the speed of the conveyor carrying the photovoltaic structure, or the laser scribing tool if it is allowed to move in the same direction as the grooves, or both. For example, if the desired groove depth should greater, one can increase the laser power of scribing tool 102, or slow down the conveyor so that the laser beam of scribing tool 102 can have more time to penetrate the photovoltaic structures. In another embodiment, instead of a continuous line, scribing tool 102 may form a discontinuous line, such as a dotted line, on the photovoltaic structure. The adjustment of the laser power, the conveyor speed, and/or the laser scribing tool's movement speed can be based on manual or automatic monitoring of the groove depth. Some monitoring may be based on optical, ultrasonic, or any other type of measurement method. The feedback can be periodical or in real time.

In some embodiments, scribing tool 102 may be mounted in such a way that it can move in a substantially horizontal plane and in a direction substantially perpendicular to the direction in which the photovoltaic structures move. This way, while photovoltaic structure 124 is moved by conveyor 120, scribing tool 102, after proper alignment, can scribe the grooves at predetermined locations on photovoltaic structure 124. In one embodiment, to allow lateral adjustment (i.e., in the direction substantially perpendicular to the direction of conveyor movement), scribing tool 102 is mounted on sliding mount 104, which may be mounted on a set of cross roller guides 108 coupled to fixed mount 106. A computer system (not shown) can align the tip of scribing tool 102, which for example can include two laser emitters, to a predetermined offset from two busbars on photovoltaic structure 124 by using actuator 110 to slide sliding mount 104 along cross roller guides 108. The computer system can receive input from verification system 118 to detect the position and alignment of photovoltaic structure 124 on conveyor 120, and use this information to adjust scribing tool 102 along cross roller guides 108. As a result, the grooves can be formed at the desired location near the busbars. The computer system can also use the position information for photovoltaic structure 124 and they speed of conveyor 120 to determine when the system can activate or deactivate scribing tool 102. In general, conveyor 120 can move photovoltaic structures from a starting point to an end point. The distance from the starting point to the end point can be selected such that, depending on the speed of conveyor 120, there is sufficient time for the verification system 118 to determine the position of photovoltaic structure 124 and adjust the lateral position of scribing tool 102. In one embodiment, this distance can be at least three times the length of a photovoltaic structure.

In general, scribing system 100 can use a variety of scribing methods to scribe grooves on photovoltaic structure 124, including, but not limited to, laser-based, mechanical (e.g. using a diamond-tipped scribing tool), acoustic, and temperature-based scribing methods. In one embodiment, scribing tool 102 can emit one or more high-intensity laser beams that may be damaging to a human operator. In some embodiments, scribing system 100 can include protective cover 114 over scribing tool 102, and can include safety switch 116 that can switch off the laser emitter(s) in scribing tool 102 (e.g., may prevent scribing tool 102 from emitting a laser beam). If an operator needs to service scribing tool 102 or the assembly line, the operator can toggle safety switch 116 to switch off the laser emitter(s) prior to removing protective cover 114. Removing protective cover 114 can allow the operator to remove a photovoltaic structure from underneath scribing tool 102 in the event that the photovoltaic structure is stuck underneath scribing tool 102, or in the event that conveyor 120 is stopped for any reason.

Some conventional solar panels include a single string of serially connected un-cleaved solar cells. As described in U.S. patent application Ser. No. 14/563,867, it can be more desirable to have multiple (such as 3) strings, each string including cascaded strips, and connect these strings in parallel. Such a multiple-parallel-string panel configuration provides the same output voltage with a reduced internal resistance. In general, a cell can be divided into n strips, and a panel can contain n strings, each string having the same number of strips as the number of regular solar cells in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string (note that the total resistance of a string made of a number of strips can be a fraction of the total resistance of a string made of the same number of undivided cells). Therefore, in general, the greater n is, the lower the total internal resistance of the panel is, and the more power one can extract from the panel. However, a tradeoff is that as n increases, the number of connections required to inter-connect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance is, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver-paste or aluminum based electrode may require n to be greater than 4, because process of screen printing and firing silver paste onto a cell does not produce ideal resistance between the electrode and underlying photovoltaic structure. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n is selected to be three, which is less than the n value generally needed for cells with silver-paste electrodes or other types of electrodes. Correspondingly, two grooves can be scribed on a single cell to allow the cell to be divided to three strips.

In addition to lower contact resistance, electro-plated copper electrodes can also offer better tolerance to micro cracks, which may occur during a cleaving process. Such micro cracks might adversely impact silver-paste-electrode cells. Plated-copper electrode, on the other hand, can preserve the conductivity across the cell surface even if there are micro cracks in the photovoltaic structure. The copper electrode's higher tolerance for micro cracks allows one to use thinner silicon wafers to manufacture cells. As a result, the grooves to be scribed on a cell can be shallower than the grooves scribed on a thicker wafer, which in turn helps increase the throughput of the scribing process. More details on using copper plating to form low-resistance electrode on a photovoltaic structure are provided in U.S. patent application Ser. No. 13/220,532, filed Aug. 29, 2011, entitled “SOLAR CELL WITH ELECTROPLATED GRID,” the disclosure of which is incorporated by reference in its entirety.

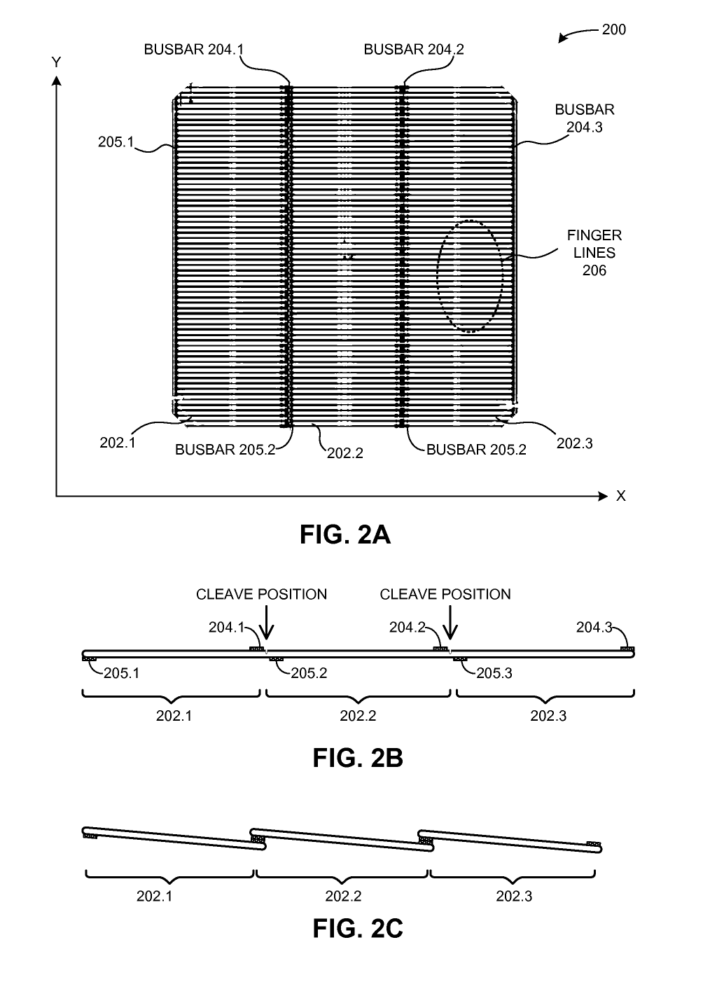

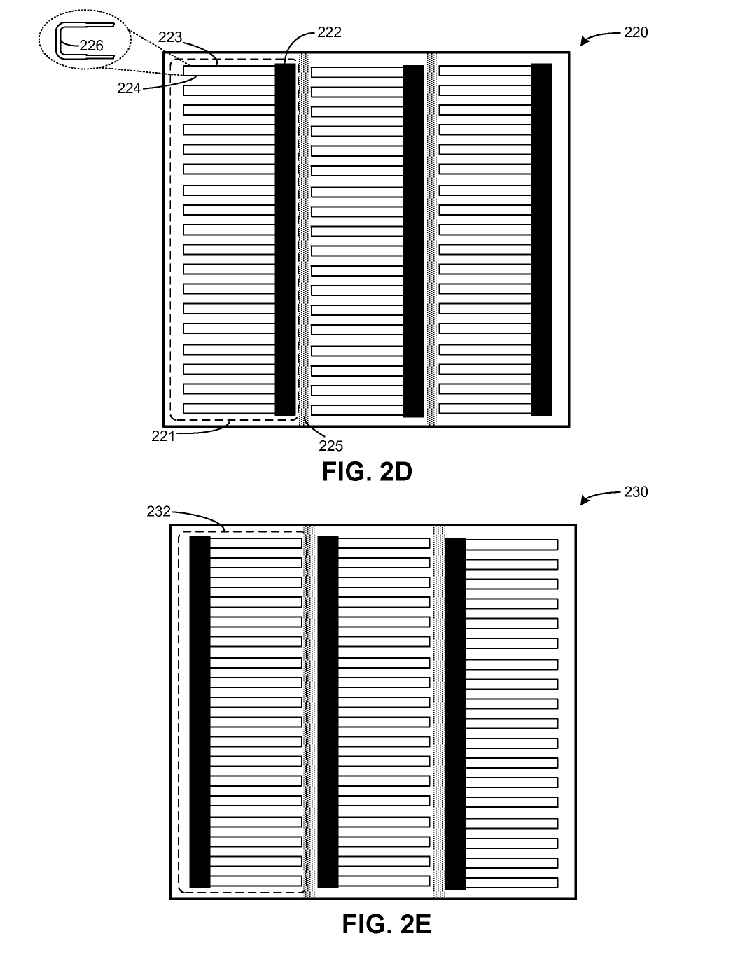

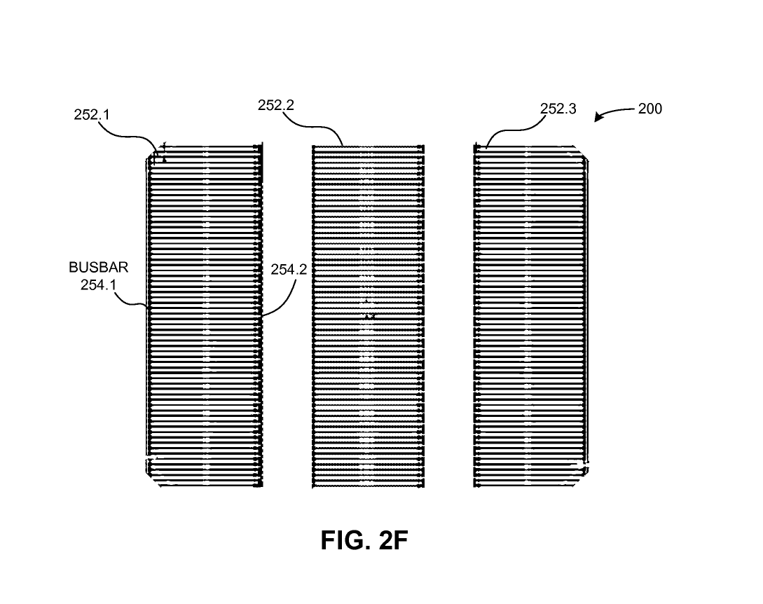

FIG. 2A shows photovoltaic structure 200 according to one embodiment of the invention. Photovoltaic structure 200 can include three photovoltaic strips 202.1, 202.2, and 202.3, which can be the result of photovoltaic structure 200 having an electroplated copper electrode that exhibits low contact resistance. Each strip can include a number of substantially parallel finger lines, such as finger lines 206, arranged in the X direction. These finger lines can collect the carriers generated by the photovoltaic structure and allow them to move toward a busbar. The busbar can be any electrically conductive element such as a metallic strip, often wider than a finger line, arranged in the Y direction. The busbar then can aggregate the current collected by the finger lines. Each strip can include two busbars, one on each surface, positioned on opposite edges. For example, strip 202.1 can have busbar 204.1 on the top surface, and busbar 205.1 on the bottom surface. Similarly, strip 202.2 can have busbars 204.2 and 205.2 on the top and bottom surfaces, respectively, and strip 202.3 can have busbars 204.3 and 205.3 on the top and bottom surfaces, respectively. In one embodiment, photovoltaic structure 200 can be scribed near and along busbars 204.1 and 204.2, which allows photovoltaic structure 200 to be subsequently cleaved into three strips along these grooves. Additional busbars may be added to either surface to reduce resistance.

FIG. 2B shows a cross-sectional view of photovoltaic structure 200 prior to being cleaved, according to one embodiment of the invention. Two scribed grooves can be located between busbars 204.1 and 205.2, and between busbars 204.2 and 205.3, respectively. These grooves correspond to the cleave positions. After the subsequent cleaving process, the entire photovoltaic structure can be divided, for example, to three strips 202.1, 202.2, and 202.3.

FIG. 2C shows a cascaded arrangement of three strips after a photovoltaic structure is cleaved, according to one embodiment of the invention. In this example, three strips 202.1, 202.2, and 202.3 can be arranged in a cascaded manner, such that the positive-side busbar of one strip overlaps and is electrically coupled to the negative-side busbar of the neighboring strip. A conductive paste can be applied between two facing busbars to facilitate both low-resistance contact and physical bonding. Because no conductive tabs or wires are used, such a cascading arrangement can reduce the series resistance due to inter-connection between to strips, and can improve the fill-factor of the panel.

FIG. 2D shows an exemplary conductive grid and blank space pattern on the front surface of a photovoltaic structure, according to one embodiment. In the example shown in FIG. 2D, conductive grid 220 can be made of any electrically conductive material, including metallic and non-metallic materials. Conductive grid 220 can include three sub-grids, such as sub-grid 221. The photovoltaic structure can also include a blank space (i.e., space not covered by electrodes) between neighboring sub-grids, such as blank space 225. The blank space provides the area where scribing and cleaving can occur. Because the blank space is not covered with any conductive material, the scribing and cleaving can occur without contacting the electrode. Each sub-grid can function as the front-side grid for the corresponding strip. Hence, this sub-grid-and-blank-space configuration can allow the photovoltaic structure to be divided into three strips. In general, a respective sub-grid can have various types of patterns. For example, a sub-grid can have two, instead of one, busbars, or a single busbar placed in the center of the strip. In the example shown in FIG. 2D, the sub-grids can each have a single busbar pattern placed on the edge, which allows the strips to be cascaded.

FIG. 2E shows an exemplary conductive grid and blank space pattern on the back surface of a photovoltaic structure. In this example, back conductive grid 230 can include three sub-grids. In one embodiment, the backside sub-grids may correspond to the front side sub-grids. As a result, the backside of the strips can also absorb light to generate electrical energy, thereby allowing the solar panel to operate in a bifacial manner. In the embodiment shown in FIGS. 2D and 2E, the front and backside sub-grids can have similar patterns except that the front and back edge-busbars are located near opposite edges of the strip. In other words, the busbar on the front side of the strip may be located at one edge, and the busbar on the back side may be located at the opposite edge. In addition, the locations of the blank spaces on the back side may be aligned with the locations of the blank spaces on the front side, such that the conductive grid lines may not interfere with the subsequent cleaving process.

In the embodiment shown in FIGS. 2D and 2E, each sub-grid may include an edge-busbar running along the longer edge of the corresponding strip and a plurality of parallel finger lines running in a direction substantially parallel to the shorter edge of the strip. For example, in FIG. 2D, sub-grid 221 may include edge-busbar 222, and a number of finger lines, such as finger lines 223 and 224. A blank space, which is not covered by any conductive material, can be placed between two adjacent sub-grids to facilitate the subsequent scribe and cleaving process. Note that in FIG. 2D the ends of the finger lines can be connected by a conductive line to form “loops.” This type of “looped” finger line pattern can reduce the likelihood of the finger lines from peeling away from the photovoltaic structure after a long period of usage. For example, as shown in FIG. 2D, finger lines 223 and 224 are connected by conductive line 226 to form a loop with rounded corners. Optionally, the sections where the finger lines are joined can be wider than the rest of the finger lines to provide more durability and prevent peeling. Other finger line patterns, such as un-looped straight lines or loops with different shapes, are also possible.

As shown in FIG. 2D, strip-shaped blank space 225, shown in a shaded rectangle, can separate sub-grid 221 from its adjacent sub-grid. The width of the blank space, such as blank space 225, is chosen to provide sufficient area for the laser scribing process without causing any potential damage to the nearby electrodes, and yet sufficiently narrow so that the electrodes can reach the edge of each strip and provide low-resistance collection of the carriers. There may be a tradeoff between a wider blank space that facilitates more error-tolerant scribing operation and a narrower blank space that results in more effective current collection. In one embodiment, the blank space width can be between 0.5 mm and 2 mm. In a further embodiment, the width of such a blank space may be 1 mm.

As mentioned above, in order to prevent damage to the emitter junction of the photovoltaic structure, the scribing operation may be performed on the surface corresponding to the surface field layer. For example, if the emitter junction is on the front side of the photovoltaic structure, the laser scribing may occur to the back surface of the photovoltaic structure. On the other hand, if the emitter junction is on the back side, the laser scribing may occur on the front surface of the photovoltaic structure. FIG. 2F shows multiple strips 252.1, 252.2, and 252.3, which are the result of separating a photovoltaic structure along a set of grooves, according to one embodiment of the invention. Each strip can include two busbars, one on each side, on opposite edges. For example, strip 252.1 can include separate busbars 254.1 and 254.2 on the front side and back side, respectively.

### Cell-Cleaving Assembly Line

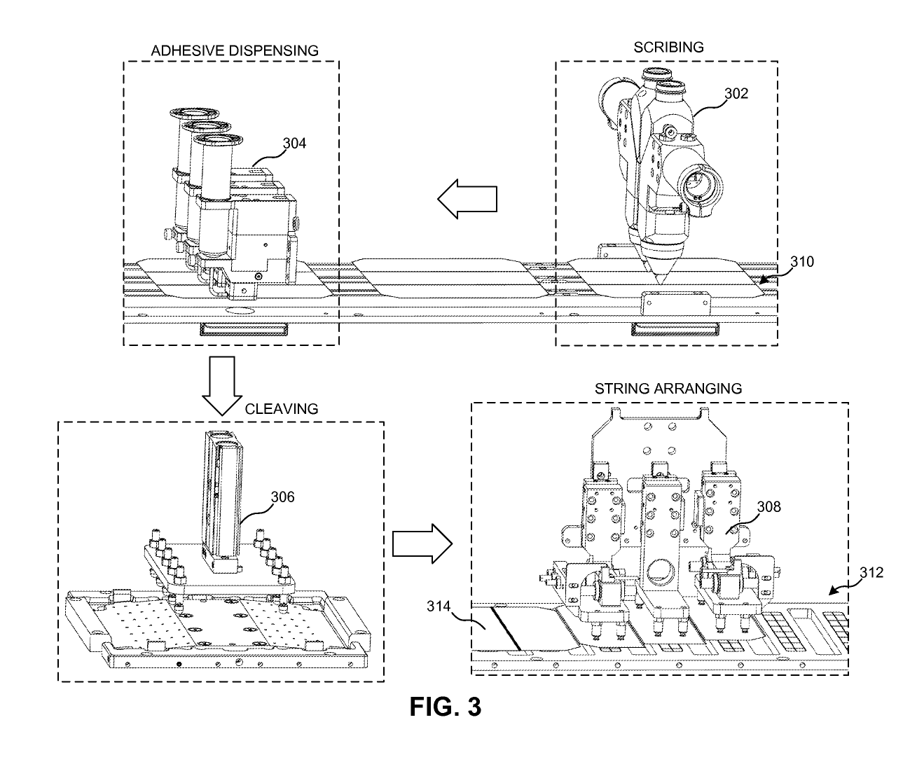

FIG. 3 shows a sequence of steps for processing photovoltaic structures to produce a string according to one embodiment of the invention. In this example, conveyor 310 can transfer photovoltaic structures to scribing apparatus 302, which can scribe one or more grooves along the busbars of each photovoltaic structure. Conveyor 310 can then transfer the photovoltaic structures to adhesive-dispensing apparatus 304, which can dispense a conductive adhesive paste on busbars of the strips, so that after cleaving these strips can be bonded together in a cascaded arrangement.

After application of the conductive adhesive paste, the photovoltaic structures can be picked up from conveyor 310 by, for example, a robotic arm (not shown) via a suction device that may be integrated into the robotic arm. The robotic arm can hold the photovoltaic structure by maintaining the suction force while transferring the photovoltaic structure toward cleaving apparatus 306. The robotic arm can rotate photovoltaic structures approximately 90 degrees before placing it onto a loading mechanism of cleaving apparatus 306. The loading mechanism may also include a buffer where the cells can be stored before being moved to cleaving apparatus 306.

Cleaving apparatus 306 can receive photovoltaic structures from the loading mechanism, and cleave the photovoltaic structures into strips along the grooves formed by scribing tool 302. After a photovoltaic structure is cleaved into a number of (e.g., three) strips, string-arrangement apparatus 308 can lift these strips and arrange the strips in a cascaded arrangement while moving the strips to string-processing table 312. String-arrangement apparatus 308 can overlap a leading edge of the three cascaded strips over the trailing edge of a previously formed string 314, thereby extending string 314.

The sequence of operations shown in FIG. 3 is one of many ways to manufacture cascaded strings. For example, the step of applying the conductive adhesive paste can occur before scribing or after cleaving. Furthermore, a variety of apparatuses can be used to implement the functions showing in FIG. 3.

### Scribing Apparatus

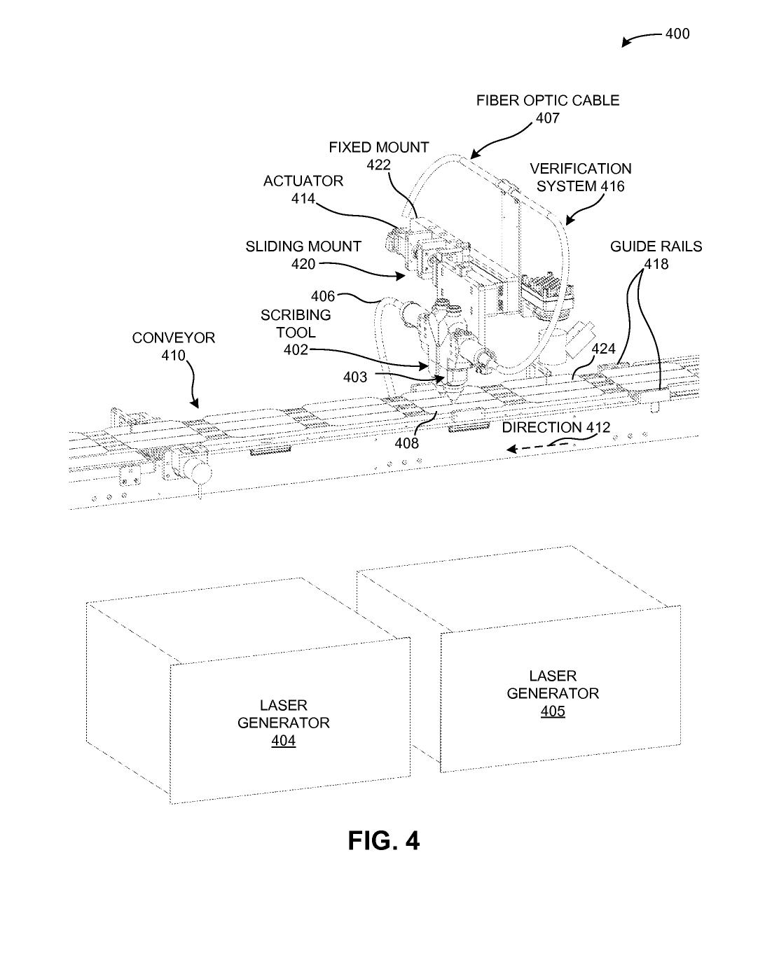

FIG. 4 shows scribing system 400 according to an embodiment of the present invention. Scribing system 400 can include one or more scribing tools, such as scribing tools 402 and 403, and can include conveyor 410 that moves photovoltaic structures in direction 412 toward scribing tools 402 and 403. Scribing tools 402 and 403 can scribe grooves near and substantially parallel to two inner busbars of photovoltaic structure 408, as conveyor 410 moves photovoltaic structure 408 underneath scribing tools 402 and 403 along direction 412. Note that in one embodiment the tolerance for the grooves being “substantially parallel” to the busbars can be represented as an angle between a respective groove and the corresponding busbar. Ideally, this angle is zero. The tolerance for variation of this angle may be determined by the tolerance of variation between the areas of the resulting strips. In general, it is preferable that all the strips in a string have the same area, because different strip areas may result in decreased total current (power) output. A small variation in strip area can be tolerated. Correspondingly, this area variation between the strips can be translated to a variation of the angle between the groove and busbar. In one embodiment, as long as the angle between the groove and the bus bar is within this angle variation, the groove can be considered “substantially parallel” to the busbar.

Scribing system 400 can include two laser generators 404 and 405 that generate a high-energy laser beam for scribing tools 402 and 403, respectively. Scribing tools 402 and 403 can receive these high-energy laser beams via fiber optic cables 406 and 407. In this embodiment, two laser beams can scribe photovoltaic structure 408 along two parallel lines as photovoltaic structure 408 moves under the laser beams. As a result, photovoltaic structure 408 can subsequently be divided into three strips along these grooves. Optionally, a single laser beam can be divided by, for example, a beam splitter into two beams, and these two beams can scribe the two grooves on the photovoltaic structure. In a further embodiment, a reflecting device driven by a motor can reflect a single laser beam alternately to two locations corresponding to the two grooves, thereby forming the two grooves (which might not be a continuous line).

In another embodiment, a single laser scribing module containing a beam-splitter that splits a laser beam into two beams may be used for scribing the photovoltaic structures. The distance between the two beams on a top surface of the photovoltaic structure can be substantially equal to the separation distance between the inner busbars of the photovoltaic structure.

Depending on the layout of the electrode layers on the photovoltaic structures, it may be desirable to divide the photovoltaic structures into fewer or more than three strips. Correspondingly, fewer or additional scribing tools (e.g., laser scribing tools) and/or beam splitters can be configured to scribe the photovoltaic structures at the desired locations. The scribe lines can divide the surface area of photovoltaic structure 408 into strips that have the same length or different lengths. In addition, each strip may have the same width or different widths. The total surface area of the strips may be the same if square-shaped photovoltaic structures are used. However, in some embodiments, the total area of each strip can be different if photovoltaic structures with chamfered corners are used. This type of photovoltaic structure may result in three strips where the two outer strips may have approximately the same surface area, which can be less than that of the strip in the middle. In one embodiment, the width of each strip of the same photovoltaic structure can be configured such that the resulting strips have substantially the same area, while the widths of these strips may be different to compensate for different corner shapes (such as the chamfered corners of outer strips and square corners of inner strips).

In some embodiments, scribing system 400 can include a pair of guide rails 418 that may align the photovoltaic structures (and/or the busbars of each photovoltaic structure) to be parallel to direction 412. As a result, the grooves can be substantially aligned with the busbars. Scribing system 400 can also include verification system 416 that may include a vision system (e.g., a camera) that can capture images of the photovoltaic structures. A computer controller can run an image processing application to compare the captured image with a reference image of a photovoltaic structure being in the correct position on conveyor 410. As a result of this comparison, one or more actuators can move guide rails 418 on each side of conveyor 410 to adjust the position of the photovoltaic structures as needed so that the grooves can be formed at the intended positions.

In some cases, scribing tools 402 and 403 might be displaced and become too close or too far from the two inner busbars when the photovoltaic structure reaches scribing tools 402 and 403. To address this problem, scribing system 400 can include a computer system that can determine, using for example data collected by verification system 414, the position of the busbars and/or the position of a leading edge on photovoltaic structure 424 relative to the position of scribing tools 402 and 403. The computer system can then use this position information to adjust the lateral position (i.e., perpendicular to direction 412 in the horizontal plane) of scribing tools 402 and 403 prior to photovoltaic structure 424 reaching scribing tools 402 and 403, so that the tip (and the laser beam) of scribing tools 402 and 403 may be at or within a predetermined distance from the inner busbars of photovoltaic structure 424. In one embodiment, the computer system can activate actuator 414 to move sliding mount 420 along a set of cross roller guides on fixed mount 422 to adjust the lateral position of scribing tools 402 and 403. Scribing tools 402 and 403 can also be turned on and off, or have their power varied, during movement.

The computer system can also be configured to monitor the position for photovoltaic structure 424 and the speed of conveyor 410. In one embodiment, the computer system can monitor photovoltaic structure 424's position relative to scribing tools 402 and 403, or to any other fixed point in the three-dimensional space. The computer system can then activate scribing tools 402 and 403 when a leading edge of photovoltaic structure 424 moves under the tips of scribing tools 402 and 403. Subsequently, the computer system can deactivate scribing tools 402 and 403 when a trailing edge of photovoltaic structure 424 reaches the tips of scribing tools 402 and 403.

During operation, it is possible that guide rails 418 may not always align the busbars of all photovoltaic structures to be parallel to direction 412. Such misalignment may result in scribing tools 402 and 403 scribing a groove that is not parallel to a busbar, and may instead cut into the busbar or into one or more finger lines. In some embodiments, the computer system can activate actuator 414 to adjust scribing tools 402 and 403 based on the real-time position of the busbars, such that the grooves are formed at the target distance from the inner busbars while photovoltaic structure 424 passes under scribing tools 402 and 403. For example, the computer system can periodically calculate the position of the inner busbars of photovoltaic structure 408 while conveyor 410 moves photovoltaic structure 408 under scribing tools 402 and 403. The computer system can control actuator 414, based on the calculated positions of the busbars, to continuously or periodically re-align scribing tools 402 and 403 with the inner busbars of photovoltaic structure 408 as conveyor 410 moves photovoltaic structure 408 by scribing tools 402 and 403.

In another embodiment, the width of conveyor 410 may be such that it matches the width of the photovoltaic structures with a predetermined tolerance that can prevent the photovoltaic structures from becoming misaligned. Hence, when the photovoltaic structures are loaded onto conveyor 410, they may remain in the intended position since there is no room for them to move orthogonally to the direction of conveyor 410's movement. In further embodiments, conveyor 410 can be wider than the width of the photovoltaic structures. Guide rails 418 can retain the photovoltaic structures in the desired position.

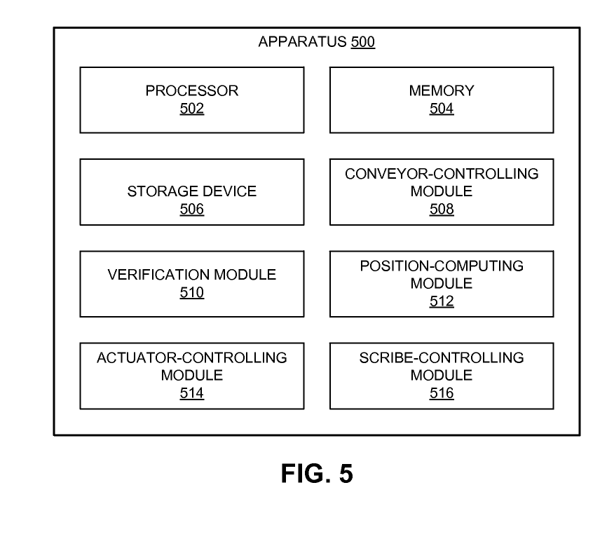

FIG. 5 shows exemplary scribe-controlling apparatus 500 according to an embodiment of the invention. Apparatus 500, which can include the aforementioned computer system, can include a number of modules which may communicate with one another via a wired or wireless communication channel. Apparatus 500 may be realized using one or more integrated circuits, and may include fewer or more modules than those shown in FIG. 5.

Scribe-controlling apparatus 500 can include processor 502, memory 504, and storage device 506. Memory 504 can include volatile memory (e.g., RAM) that serves as a managed memory, and can be used to store one or more memory pools. In some embodiments, storage device 506 can store an operating system, and instructions for monitoring and controlling the cell-scribing process.

In this example, apparatus 500 can include conveyor-controlling module 508, verification module 510, position-computing module 512, actuator-controlling module 514, and scribe-controlling module 516. Conveyor-controlling module 508 can cause a conveyor to move photovoltaic structures from a loading station to the scribing station, and subsequently toward a cleaving and testing station. Verification module 510 can analyze images from a vision system to determine the location of a photovoltaic structure on the conveyor, and determine the alignment of the photovoltaic structure and its busbars.

Position-computing module 512 can periodically (e.g., at predetermined time intervals) calculate the position of the photovoltaic structure relative to the scribing tool, while the conveyor moves the photovoltaic structure away from the vision system. For example, position-computing module 512 can calculate the photovoltaic structure's position based on an image captured by the vision system, a corresponding time stamp, and the speed o the conveyor. Actuator-controlling module 514 can activate an actuator to align the scribing tool to a predetermined distance from the corresponding busbar, for example, prior to the photovoltaic structure reaching the scribing tool, or while the conveyor is moving the photovoltaic structure underneath the scribing tool. Scribe-controlling module 516 can activate the scribing tool at a predetermined position (e.g., when the position of a leading edge of the photovoltaic structure reaches the scribing tool), and subsequently deactivate the scribing tool at another position (e.g., when the position of a trailing edge of the photovoltaic structure reaches the scribing tool).

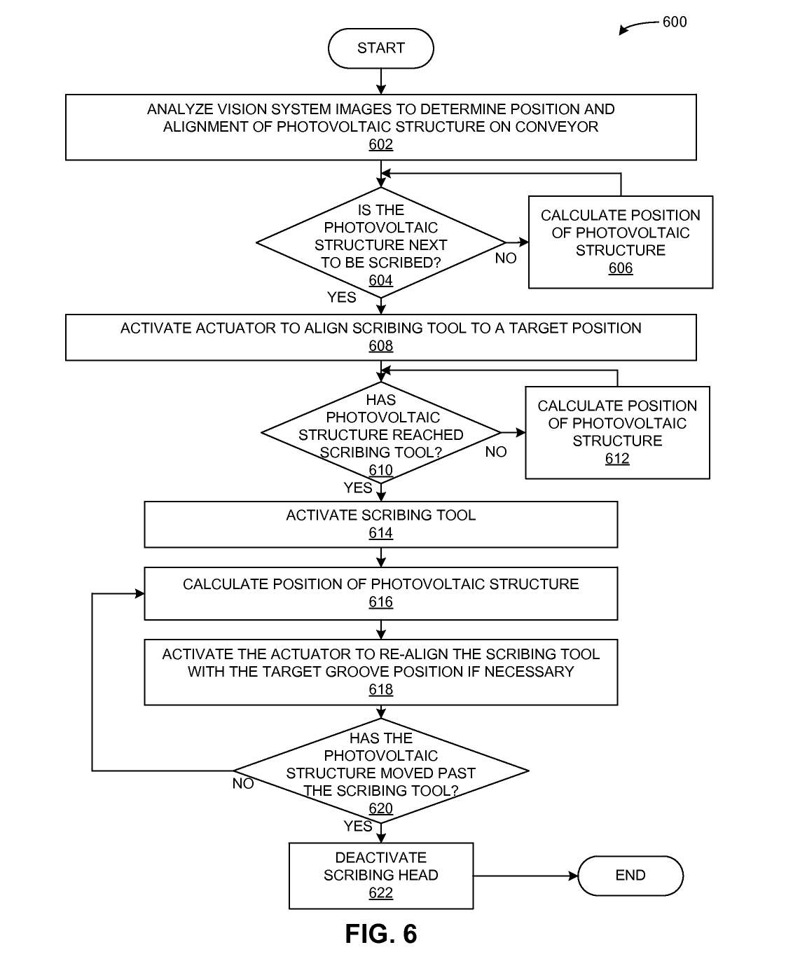

FIG. 6 shows a method for scribing a groove near inner busbars of a photovoltaic structure, according to an embodiment of the invention. During operation, a verification system can analyze images from a vision system to determine the position of the photovoltaic structure on the conveyor, and can determine the alignment of the photovoltaic structure and its busbars with respect to the scribing tools (operation 602). As the conveyor moves the photovoltaic structure toward the laser scribing tool, a computer system can determine whether the photovoltaic structure is the next to be scribed (operation 604). If the laser scribing tool is active and scribing another photovoltaic structure, the computer system can periodically calculate the position of the photovoltaic structure as it moves along the conveyor (operation 606) before determining again whether the photovoltaic structure is the next to be scribed (operation 604).

When the photovoltaic structure is the next to be scribed, the computer system can activate an actuator on a laser-scribe mount that can align the scribing head of the laser scribing tool to a target groove position on the photovoltaic structure (operation 608), for example at a predetermined distance from a busbar. The computer system can then periodically determine whether the photovoltaic structure has reached the laser scribing tool (operation 610), and can calculate the position of the photovoltaic structure before it reaches the laser scribing tool (operation 612).

When the computer system determines that a leading edge of the photovoltaic structure has reached the scribing head, the computer system can activate the laser scribing tool (operation 614). In one embodiment, the laser scribing tool can be activated by opening an aperture of the scribing head to allow the laser beam to pass through. The computer system can then periodically calculate the position of the photovoltaic structure (operation 616). In case the photovoltaic structure is not properly aligned on the conveyor, the computer system can re-align the scribing head with the target groove position while the conveyor moves the photovoltaic structure underneath the laser scribing tool (operation 618).

The computer system can determine whether the photovoltaic structure has moved past the laser scribing tool, based on its updated position (operation 620). If the photovoltaic structure has not moved past the laser scribing tool, the computer system can return to operation 616 to calculate its position as the conveyor moves the photovoltaic structure. When a trailing edge of the photovoltaic structure has reached or moved past the laser scribing tool, the computer system can deactivate the scribing head by, for example, closing the aperture of the laser scribing head (operation 622). At this point, the laser scribing tool is ready to receive another photovoltaic structure.

In some embodiments, the computer system can perform multiple instances of process 600 in parallel. Each instance is run for a respective photovoltaic structure that may have reached the verification system, be in transit to the laser scribing tool, or may be in the process of being scribed by the laser scribing tool. In some other embodiments, the computer system can perform a variation of process 600 that can take position and alignment information for multiple photovoltaic structures into account while simultaneously operating the verification system, the actuator, and/or the laser scribing tool.

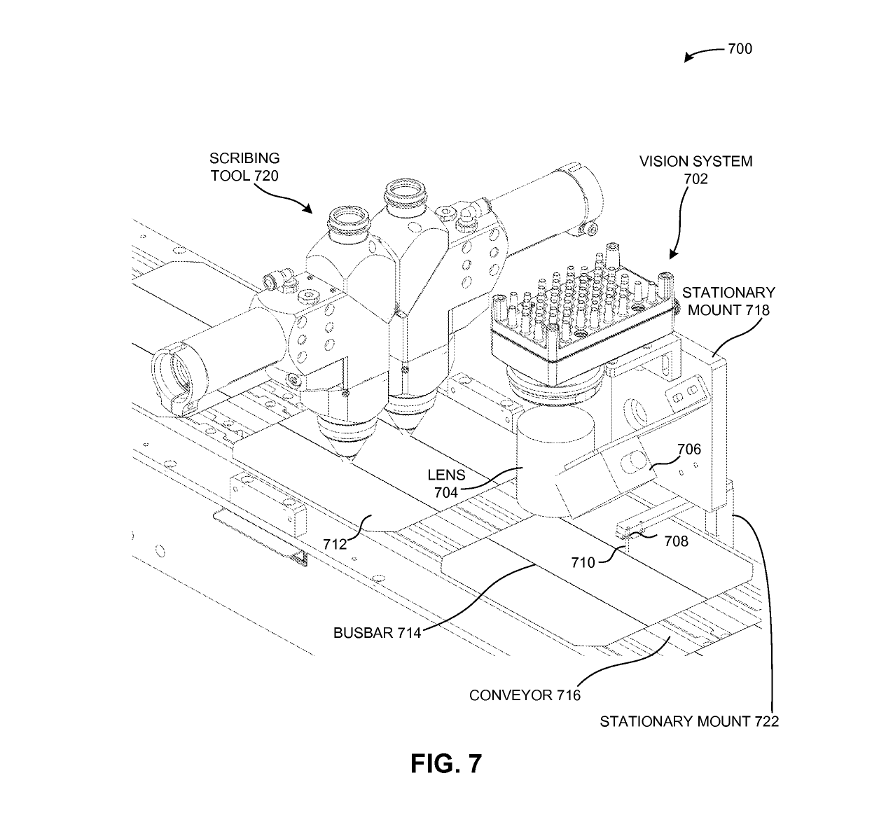

FIG. 7 shows exemplary photovoltaic structure verification station 700 according to an embodiment of the present invention. Station 700 can include vision system 702, which can capture images of photovoltaic structures on conveyor 716. A computer system can use the captured images to determine the position and orientation of photovoltaic structure 712. For example, the computer system can determine the position of a leading edge and a trailing edge of photovoltaic structure 712 at a given time based on an image of photovoltaic structure 712, a corresponding timestamp, and the speed of conveyor 716. The computer system can also determine the alignment of busbar 714 based on a captured image of the photovoltaic structure. For example, the computer system can measure an angle between a busbar in a captured image and a reference object, such as a guide rail. If a photovoltaic structure is not oriented properly (e.g., the angle between its busbars and a guide rail is greater than a threshold), the computer system may prevent scribing a groove on the photovoltaic structure and allow the photovoltaic structure to fall down a chute at the end of conveyor 716 and into a bin (not shown). In some embodiments, vision system 702 can include a high-resolution line-scan vision system that can construct an image while photovoltaic structure 712 passes vision system 702.

In some embodiments, vision system 702 and lens 704 can be mounted on stationary mount 718, which allows the computer to compute the position and orientation of photovoltaic structure 712 with reference to a fixed point. The computer system can associate the position and orientation information, as well as a timestamp of each captured image, with each photovoltaic structure passing underneath lens 704. Thereafter, as conveyor 716 moves photovoltaic structure 712 toward laser scribing tool 720, the computer system can predict the movement of photovoltaic structure 712 using the corresponding position and timestamp information and the speed of conveyor 716. For example, the computer system can predict when the leading edge of photovoltaic structure 712 will reach the laser beam emitted by laser scribing tool 720 based on the distance between the photovoltaic structure's leading edge and the laser beam, the time when vision system 702 captures the image, and the speed of conveyor 712.

In some embodiments, lens 704 can have a focal length of approximately 50 mm, with an iris range between F/1.8 and F/22. Moreover, an external spot light 706 can be mounted near lens 704 to improve image contrast. The computer system can analyze these high-contrast images to separate photovoltaic structure 712 from a background (e.g., from conveyor 716), and to identify features of photovoltaic structure 712 (e.g., busbar 714 and a perimeter of photovoltaic structure 712).

Photovoltaic structure verification station 700 can also include photoelectric sensor 708 and light emitter 710 to detect the presence of a photovoltaic structure on conveyor 716. In one embodiment, light emitter 710 can shine a beam of light on a photovoltaic structure. Because the light reflected off the photovoltaic structure can be substantially different (e.g., brighter) from the light reflected off conveyor 716, photoelectric sensor 708 can generate a signal when difference in the intensity of reflected light is detected. The computer system can periodically sample this signal and detect the presence of a photovoltaic structure.

Upon detecting the presence of a photovoltaic structure based on a signal from photoelectric sensor 708, the computer system can instruct vision system 702 to capture images of the photovoltaic structure. In turn these images can be used to calculate the alignment of the busbars and predict, based on the timestamp of the captured image and the speed of conveyor 716, when the photovoltaic structure will arrive at the target position. Correspondingly, the computer system can determine how to align laser scribing tool 720 and/or when to activate or deactivate laser scribing tool 720. In some embodiments, the computer system can use signal from photoelectric sensor 708 to detect the position of the leading edge and trailing edge of photovoltaic structure 712, and use this position information to activate and deactivate laser scribing tool 720.

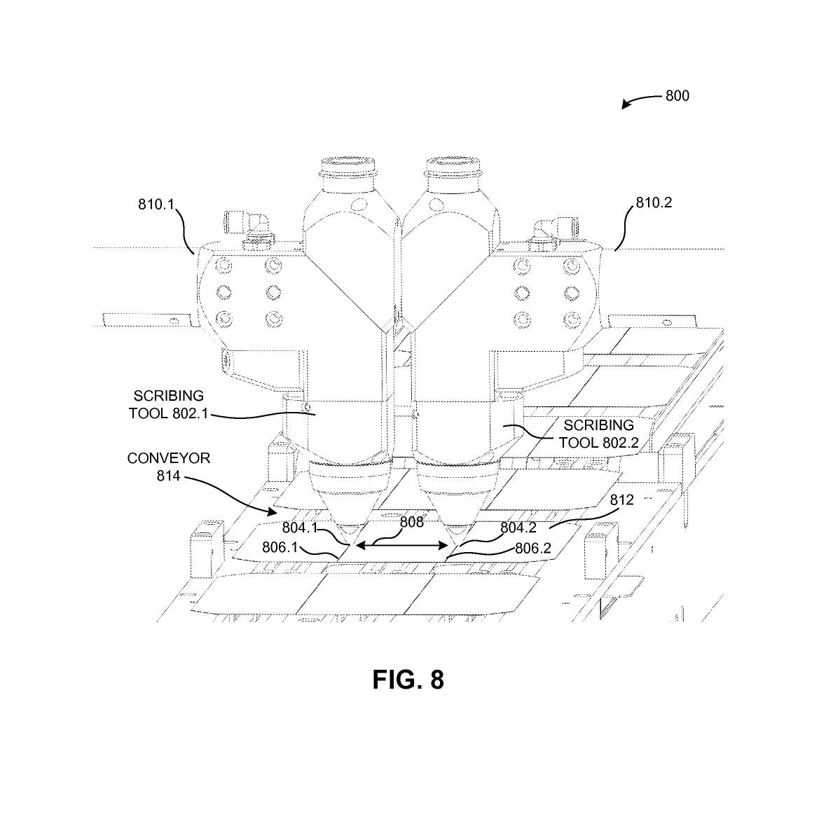

FIG. 8 shows an exemplary scribing apparatus 800 according to an embodiment of the invention. Scribing apparatus 800 can include two scribing tools 802.1 and 802.2, which can receive a high-energy laser from a corresponding laser generator (not shown) via fiber optic lines 810.1 and 810.2, respectively. In some embodiments, scribing tools 802.1 and 802.2 can be separated at distance 808, which can be substantially equal to the distance between two inner busbars 806.1 and 806.2 of photovoltaic structure 812.

Scribing tools 802.1 and 802.2 can emit a laser beam via nozzles 804.1 and 804.2, respectively. In some embodiments, each scribing tool can include an internal lens that can focus the laser beam onto a top surface of photovoltaic structure 812, which can scribe a groove with a predetermined depth. The intensity of the laser beam can be adjusted based on the desired groove depth and the speed of conveyor 814. Also, an actuator (not shown) can be used to align nozzles 804.1 and 804.2 to a predetermined distance from busbars 806.1 and 806.2, respectively.

In one embodiment, scribing apparatus 800 may include a feedback mechanism that determines whether the depth of the groove may be at the desired level. For example, the feedback mechanism may include an optical system (e.g., a laser distance gauge aimed at the groove) that can estimate the depth of the groove. The measured groove depth can then be used to adjust the intensity of the lasers, preferably in real time.

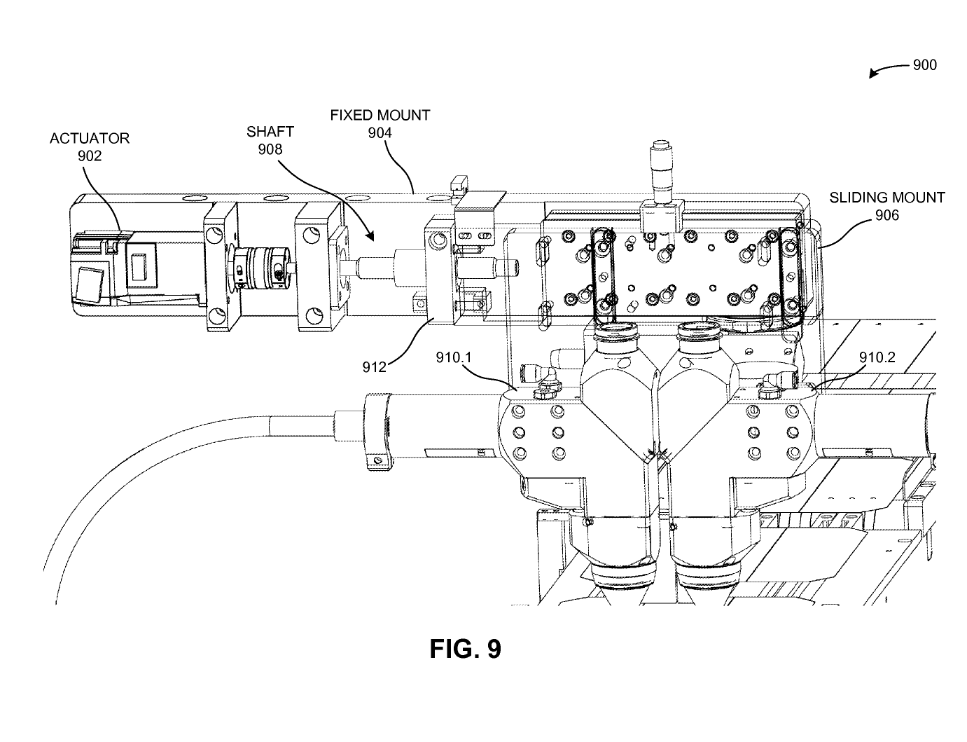

As mentioned above, the laser scribing tool can be adjusted laterally and aligned with the target groove position. A number of mechanical components can be used to facilitate controlled, precise lateral movement, as described below in conjunction with FIGS. 9-11.

FIG. 9 shows a front view of scribe mount 900 according to an embodiment of the invention. Scribe mount 900 can include fixed mount 904 mounted on a beam or frame (not shown), and actuator 902 mounted on fixed mount 904. Fixed mount 904 is shown with a solid frame, and sliding mount 906 is shown in a transparent-surface line drawing. Sliding mount 906 can be coupled to shaft 908 that can extend from actuator 902 to block 912, which is coupled to sliding mount 906.

Scribing tools 910.1 and 910.2 can be mounted on sliding mount 906, and a computer system can move scribing tools 910.1 and 910.2 laterally by activating actuator 902. In some embodiments, actuator 902 can include an electric motor, which can convert a rotation of the internal motor's shaft into a linear motion of shaft 908. In some other embodiments, actuator 902 can include a hydraulic or pneumatic actuator that can extend or retract shaft 908. Actuator 902 can push or pull on shaft 908 to cause sliding mount 906 to slide laterally.

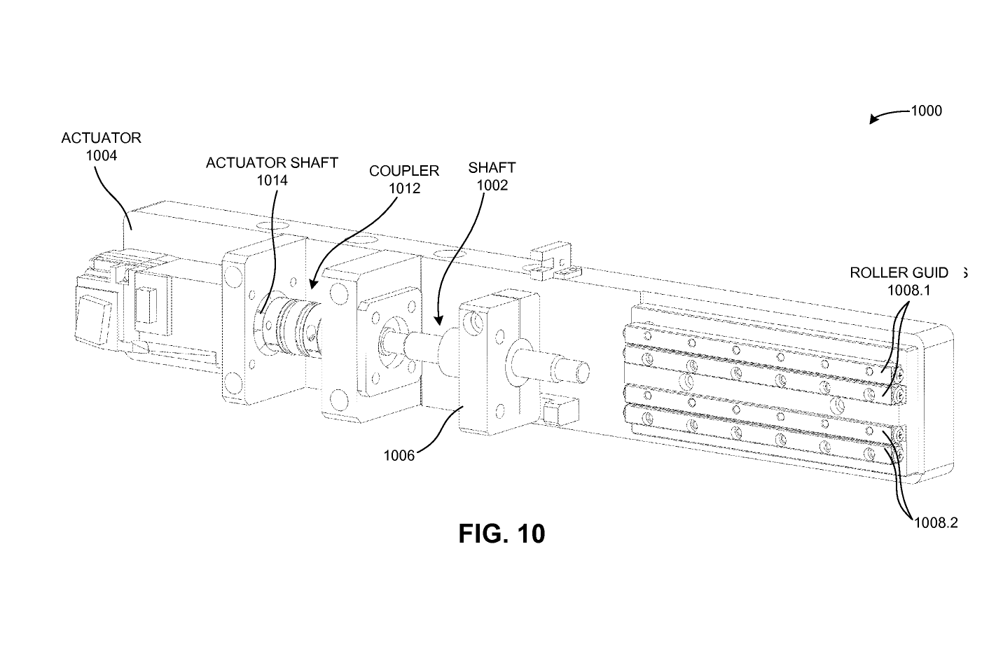

FIG. 10 shows fixed scribe mount 1000 according to an embodiment. Fixed scribe mount 1000 can include shaft 1002 coupled to actuator 1004 at one end, and coupled to block 1006 at the other end. In some embodiments, a sliding scribe mount (not shown) can be coupled to fixed scribe mount 1000 via block 1006.

Shaft 1002 may be attached to coupler 1012 which can couple shaft 1002 to actuator shaft 1014. Actuator shaft 1014 can be driven by actuator 1004 and be extended or retracted. Actuator 1004 can be, for example, an electric stepper motor that can cause actuator shaft to move at small increments, thereby facilitating fine adjustment of the lateral position of the scribing tool. As a result, shaft 1002 can push or pull block 1006, which in turn can push or pull the sliding scribe mount.

Fixed scribe mount 1000 can include top cross roller guide 1008.1 and bottom cross roller guide 1008.2, which jointly can guide the lateral motion of the sliding scribe mount. Cross roller guides 1008.1 and 1008.2 may each include a set of bearings to reduce the friction for such motion. Preferably, cross roller guides 1008.1 and 1008.2 can support the weight of the sliding scribe mount and a set of scribing tools (e.g., laser scribing tools), and may allow precise, controlled movement as the sliding scribe mount slides laterally when actuator 1004 and shaft 1002 push or pull block 1006.

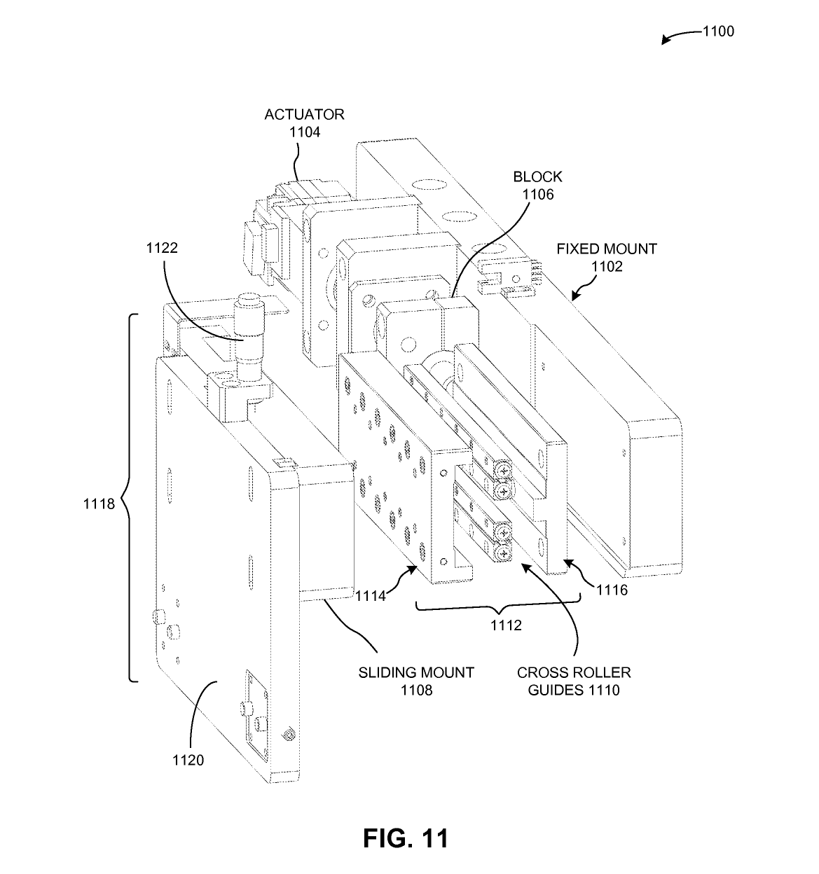

FIG. 11 shows scribing apparatus mount 1100 according to an embodiment of the invention. As described above, actuator 1104 can be attached to fixed mount 1102 and can push or pull on block 1106, which can be coupled to sliding mount 1108 via roller guide assembly 1112. Actuator 1104 can move sliding mount 1108 laterally by pushing or pulling on block 1106.

Roller guide assembly 1212 may include a front plate 1214 on which sliding mount 1208 is mounted and a rear plate 1216 mounted onto fixed mount 1202. Two sets of cross roller guides 1210 can be positioned between front plate 1214 and rear plate 1216 to facilitate lateral movement of front plate 1214.

In one embodiment, sliding mount 1108 can include vertical adjustment apparatus 1118 that can allow the mounted scribing tool to move vertically with fine increments. In one embodiment, vertical adjustment apparatus 1118 can include vertically movable plate 1120 and adjustment mechanism 1122. The scribing tools can be mounted on plate 1120, and adjustment mechanism 1122 can be used to adjust the vertical position of the mounted scribing tools. In one embodiment, adjustment mechanism 1122 can include a thimble and sleeve, similar to a micrometer, to facilitate μm-level adjustment. Other types of mechanical or electric adjustment mechanism can also be used.

In summary, the present disclosure describes a system to facilitate automatic, precise scribing of photovoltaic structures. A set of scribing tools, which can be laser based, can scribe a number of grooves on the surface of the photovoltaic structure while a conveyor moves the photovoltaic structure underneath the scribing tools. The system can use a feedback loop to adjust the scribing tool, based on the speed of the conveyor, to achieve a desired groove depth.

The methods and processes described in the detailed description section may be embodied as code and/or data, which can be stored in a computer-readable storage medium. When a computer system reads and executes the code and/or data stored on the computer-readable storage medium, the computer system can perform the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules can perform the methods and processes included within the hardware modules.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

1. A system for scribing a photovoltaic structure, the system comprising:
a conveyor that moves the photovoltaic structure along a path;
a scribing apparatus directed toward the path configured to scribe a groove of a predetermined depth on the photovoltaic structure while the photovoltaic structure moves along the path, wherein the groove does not penetrate an interface between a base layer and an emitter layer of the photovoltaic structure; and
a vision system arranged along the conveyor, the vision system configured to capture an image the photovoltaic structure on the conveyor before the photovoltaic structure is conveyed to the scribing apparatus; and
wherein the system further comprises a control module configured to operate the scribing apparatus according information derived from the image.

2. The system of claim 1, wherein the predetermined depth is approximately 2%-70% of a thickness of the photovoltaic structure.

3. The system of claim 2, wherein the predetermined depth is approximately 10%-40% of the thickness of the photovoltaic structure.

4. The system of claim 1, wherein the scribing apparatus is selected from a group consisting:
a laser scribing tool;
a mechanical scribing tool;
an acoustic scribing tool; and
a scribing tool based on temperature differential.

5. The system of claim 4, wherein the scribing apparatus comprises a laser scribing tool.

6. The system of claim 1, wherein the scribing apparatus comprises a laser scribing tool; and
wherein the control module is configured to turn on the laser scribing tool upon the photovoltaic structure reaching a first position, and turn off the laser scribing tool upon the photovoltaic structure leaving a second position.

7. The system of claim 1, further comprising:
a position detection module configured to detect a position of the photovoltaic structure based on the image; and
an alignment module configured to align the scribing apparatus based on the position of the photovoltaic structure, thereby allowing the groove to be formed at a desired position.

8. The system of claim 1, wherein the groove is formed near and substantially parallel to a busbar on the photovoltaic structure.

9. The system of claim 1, wherein the scribing apparatus comprises two scribing tools configured to scribe two grooves on the photovoltaic structure, thereby facilitating division of the photovoltaic structure into three strips.

10. The system of claim 1, wherein the scribing apparatus comprises a scribing tool and an adjustment module that facilitates adjustment of a distance between the scribing tool and a surface of the photovoltaic structure to facilitate effective scribing.

11. A method for scribing a photovoltaic structure, the method comprising:
moving a photovoltaic structure at a particular speed; and
capturing an image of the photovoltaic structure during the moving when the photovoltaic structure is at a first position;
scribing a groove of a predetermined depth on the photovoltaic structure during the moving when the photovoltaic structure arrives at a second position, the second position being spatially separated from the first position, wherein the groove does not penetrate an interface between a base layer and an emitter layer of the photovoltaic structure
wherein scribing the groove is performed according to information derived from the image.

12. The method of claim 11, wherein the predetermined depth is approximately 2%-70% of a thickness of the photovoltaic structure.

13. The method of claim 12, wherein the predetermined depth is approximately 10%-40% of the thickness of the photovoltaic structure.

14. The method of claim 11, wherein the scribing comprises one or more operations selected from a group consisting:
applying a laser beam on the photovoltaic structure;
using a mechanical scribing tool;
using an acoustic scribing tool;
applying temperature differential; and
any combination thereof.

15. (canceled)

16. The method of claim 11, wherein the scribing comprises applying a laser beam on the photovoltaic structure; and
wherein the method further comprises turning on the laser beam upon the photovoltaic structure reaching the second position, and turning off the laser beam upon the photovoltaic structure leaving the second position.

17. The method of claim 11, further comprising:
detecting a position of the photovoltaic structure based on the image; and
aligning the scribing apparatus based on the position of the photovoltaic structure, thereby allowing the groove to be formed at a desired position.

18. The method of claim 11, wherein the groove is formed near and substantially parallel to a busbar on the photovoltaic structure.

19. The method of claim 11, further comprising scribing a second groove on the photovoltaic structure, thereby facilitating division of the photovoltaic structure into three strips.

20. (canceled)

21. A scribing apparatus, comprising:
a laser scribing tool; and
a solar cell transport apparatus configured to move a solar cell past the laser scribing tool;
wherein the laser scribing tool is configured to scribe a groove on the solar cell while the solar cell moves underneath the laser scribing tool; and
wherein the groove penetrates a surface field layer but not an emitter layer of the solar cell
wherein the laser scribing tool is configured to operate according information derived from an image taken of the solar cell before the solar cell is moved to the laser scribing tool.

22. The scribing apparatus of claim 21, further comprising an alignment apparatus configured to align the laser apparatus tool based on a position of a busbar on the solar cell, thereby allowing the groove to be formed near and substantially parallel to the busbar.

23. The system of claim 1, wherein the control module is configured to operate the scribing apparatus according to a particular speed of the conveyor, position of the photovoltaic structure according to the image, and time elapsed after capture of the image.
